(19) United States
(12) Patent Application Publication
(10) Pub. No.: US 2017/0051396 A1
(43) Pub. Date: Feb. 23, 2017

(54) Method for Forming Carbon Electrode Film, Carbon Electrode, and Method for Manufacturing Phase Change Memory Element

(71) Applicant: ULVAC, INC., Kanagawa (JP)

(72) Inventors: Yuusuke Miyaguchi, Kanagawa (JP); Koukou Suu, Kanagawa (JP)

(21) Appl. No.: 15/118,681

(22) PCT Filed: Feb. 5, 2015
(86) PCT No.: PCT/JP2015/000523

§ 371 Date: Aug. 12, 2016

(30) Foreign Application Priority Data
Feb. 12, 2014 (JP) 2014-024032

(51) Int. Cl. C23C 14/35; H01L 45/00; C23C 14/06

(52) U.S. Cl. CPC C23C 14/35; C23C 14/0605; H01L 45/06; H01L 45/1253; H01L 45/16

(57) ABSTRACT

To provide a carbon electrode film forming method by which the surface roughness and the resistivity can be lowered to a predetermined value or less. A carbon electrode film forming method according to an embodiment of the present invention includes maintaining an argon gas atmosphere of 0.3 Pa to 1.2 Pa inclusive inside a chamber. By applying a power supply having a frequency of 20 kHz to 20 MHz inclusive and a power of 0.1 kW to 2 kW inclusive on a carbon target placed in the chamber, the target is sputtered. Carbon particles are deposited on a substrate placed facing the target.

### TECHNICAL FIELD

The present invention relates to a carbon electrode film forming method using sputtering, a carbon electrode formed by such a method, and a phase-change memory element manufacturing method using such a method.

### BACKGROUND ART

A NAND type flash memory is known as a nonvolatile memory. A phase-change memory element is known as a device that can be further miniaturized. The phase-change memory element is a memory element utilizing a difference in resistance value between a crystalline state and an amorphous state. The phase-change memory element is attracting attention as a nonvolatile memory that does not need supply of power for maintaining the stored data.

The phase-change memory element includes a first electrode, a second electrode, and a phase-change recording layer provided between the first electrode and the second electrode. The phase-change recording layer is formed of a material that exhibits a reversible phase change between the crystalline phase and the amorphous phase having resistance values different from each other. For example, Patent Document 1 describes a manufacturing method for a phase-change storage element including a phase-change recording layer formed of a chalcogen compound such as Ge—Sb—Te and first and second electrodes each formed of electrically conductive carbon (graphite), titanium, tungsten, or the like.

Patent Document 1: Japanese Patent Application Laid-open No. 2006-45675

### SUMMARY OF INVENTION

### Problem to be Solved by the Invention

In Patent Document 1, chemical vapor deposition, physical vapor deposition, and atomic layer deposition are exemplified as a forming method for each of the above-mentioned electrode films. However, the electrically conductive carbon film largely differs in surface characteristics and electrical characteristics depending on differences in film formation method and film formation film condition. Therefore, it is difficult to form a carbon film having an aimed film quality.

For example, if the carbon film has a high surface roughness, a phase-change recording layer formed as a film thereon cannot have desired crystalline characteristics in some cases. Otherwise, if the carbon film has a high resistivity, it leads to an increase in operating voltage of a memory element and further there is a fear that the memory element is deteriorated because the amount of heat generated increases.

In view of the above-mentioned circumstances, it is an object of the present invention to provide a carbon electrode film forming method by which a surface roughness and a resistivity can be lowered to a predetermined value or less, a carbon electrode formed by such a method, and a phase-change memory element manufacturing method using such a method.

### Means for Solving the Problem

In order to accomplish the above-mentioned object, a carbon electrode film forming method according to an embodiment of the present invention includes maintaining an argon gas atmosphere of 0.3 Pa to 1.2 Pa inclusive inside a chamber.

By applying a power supply having a frequency of 20 kHz to 20 MHz inclusive and a power of 0.1 kW to 2 kW inclusive on a carbon target placed in the chamber, the target is sputtered. Carbon particles are deposited on a substrate placed facing the target.

A carbon electrode according to an embodiment of the present invention is formed as a film by sputtering and has a surface roughness (Rq) of 0.6 nm or less and a resistivity of 1.2 Ωcm or less.

A phase-change memory element manufacturing method according to an embodiment of the present invention includes forming a first carbon electrode film. The forming a first carbon electrode film includes maintaining an argon gas atmosphere of 0.3 Pa to 1.2 Pa inclusive inside a chamber. By applying a power supply having a frequency of 20 kHz to 20 MHz inclusive and a power of 0.1 kW to 2 kW inclusive on a carbon target placed in the chamber, the target is sputtered and the first carbon electrode film is formed on a substrate placed facing the target.

A phase-change recording layer is formed on the first carbon electrode film.

### BRIEF DESCRIPTION OF DRAWINGS

FIG. 1 A schematic cross-sectional view of a sputter apparatus used in an embodiment of the present invention.

FIG. 2 A schematic cross-sectional view of a phase-change memory element according to this embodiment.

FIG. 3 An experimental result showing a change in a surface roughness (Rq) and a resistivity of a carbon film with respect to an ion impingement energy.

FIG. 4 An experimental result showing a change in the resistivity of the carbon film with respect to a discharge pressure and power in straight DC magnetron discharge.

FIG. 5 An experimental result showing a change in the resistivity of the carbon film with respect to the discharge pressure and the power in the straight DC magnetron discharge.

FIG. 6 An experimental result showing a change in the surface roughness (Rq) of the carbon film with respect to an input power in the straight DC magnetron discharge.

FIG. 7 An experimental result showing a change in a discharge voltage with respect to the input power in the straight DC magnetron discharge.

FIG. 8 An experimental result showing a change in a stress of the carbon film in the straight DC magnetron discharge.

FIG. 9 An experimental result showing a change in the surface roughness (Rq) of the carbon film with respect to the input power that is measured in each of discharge methods (straight DC, pulse DC, RF).

FIG. 10 An experimental result showing a change in the resistivity of the carbon film with respect to the input power that is measured in each of the discharge methods (straight DC, pulse DC, RF).

### MODE(S) FOR CARRYING OUT THE INVENTION

The present inventors found that a surface roughness and a resistivity of a carbon film formed by sputtering depend on a DC self bias (Vdc) generated in a stage surface supporting a substrate, and thus completed the present invention. Vdc can be set depending on the discharge method, the pressure, the magnitude of electric power applied to a target, and the like.

From the experiments by the present inventors, it was confirmed that, as Vdc became larger, the surface roughness of the carbon film formed became lower while the resistivity thereof became higher. If the carbon film is formed by sputtering with Ar plasma, as Vdc becomes larger, the energy of Ar ions entering the surface of the formed carbon film becomes larger. As a result, the surface roughness of the carbon film tends to be higher. However, it was confirmed that, when the incident energy of Ar ions becomes equal to or larger than a replacement energy (to 50 eV) of the carbon film, the surface of the carbon film is densified due to impingement with Ar ions and consequently the surface roughness becomes lower. Meanwhile, when Ar ions having that energy enter the carbon film, the resistivity of the carbon film increases. It may be because a ratio in which electrons in sp2 orbital of the carbon film transition to sp3 orbital increases.

In view of this, in an embodiment of the present invention, the DC self bias (Vdc) is limited to such a magnitude that the surface of the carbon film is not roughened by the incident energy of Ar and at the same time the resistivity of the carbon film is lowered.

The carbon electrode film forming method according to the embodiment of the present invention includes maintaining an argon gas atmosphere of 0.3 Pa to 1.2 Pa inclusive inside a chamber.

By applying a power supply having a frequency of 20 kHz to 20 MHz inclusive and a power of 0.1 kW to 2 kW inclusive on a carbon target placed in the chamber, the target is sputtered and carbon particles are deposited on the substrate placed facing the target.

According to the method above, a carbon electrode film having a surface roughness (Rq: root-mean-square roughness) of 0.6 nm or less and a resistivity of 1.2 Ωcm or less can be formed.

The DC self bias (Vdc) becomes smaller as the pressure inside the chamber becomes higher. Further, the DC self bias (Vdc) becomes smaller as the frequency of the power supply applied on the target becomes higher and the DC self bias (Vdc) becomes larger as the power of that power supply becomes higher. Therefore, by appropriately adjusting the above-mentioned pressure, frequency, and power, it becomes possible to control the surface roughness and the resistivity of the carbon electrode film to be formed.

For example, by setting the pressure inside the chamber to 0.6 Pa, and setting the frequency and the power of the power supply applied on the target to 13.56 MHz and 1 kW, respectively, a carbon electrode film having a surface roughness (Rq) of 0.5 nm or less and a resistivity of 1 Ωcm or less can be formed.

Although RF magnetron sputtering is typically employed for the discharge method, it is not limited thereto and pulse DC magnetron sputtering may be employed. By using an RF power supply or a pulse DC power supply as the power supply, the DC self bias (Vdc) of the stage surface can be lowered in comparison with the case of using a straight DC power supply.

Hereinafter, an embodiment of the present invention will be described with reference to the drawings.

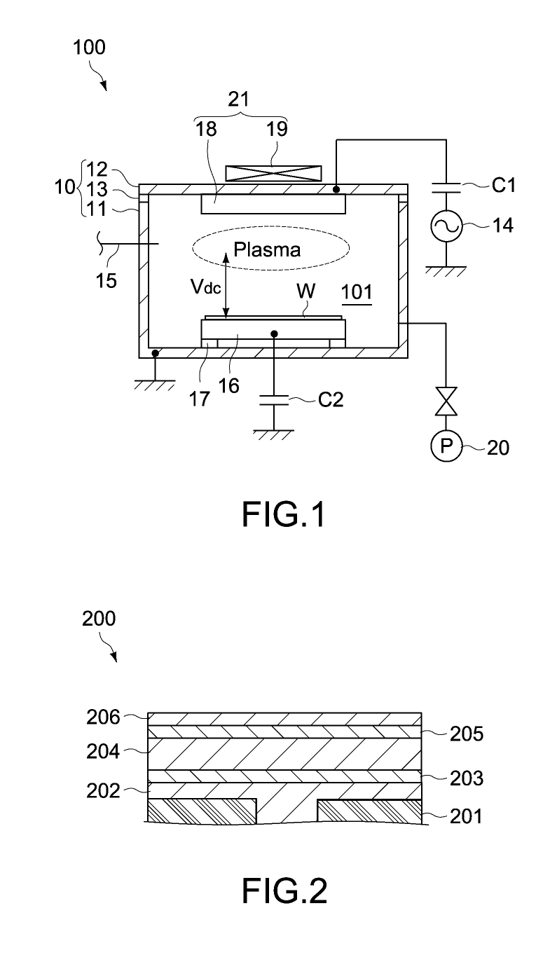

FIG. 1 is a schematic cross-sectional view of a sputter apparatus used in the embodiment of the present invention.

A sputter apparatus 100 includes a chamber 10. The chamber 10 includes a chamber body 11 opened at an upper end thereof, a lid 12 that refers to the upper end of the chamber body 11, and an insulating member 13 that provides insulation between the chamber body 11 and the lid 12. The chamber body 11 is connected to a ground potential and the lid 12 is connected to an RF power supply 14 via a blocking capacitor C1.

The chamber 10 defines a processing chamber 101 therein. The chamber 10 is capable of decompressing a processing chamber 101 to a predetermined degree of vacuum via a vacuum discharge pump. Further, a gas introduction tube 15 for introducing Ar (argon) gas into the processing chamber 101 is provided in the chamber 10.

A stage 16 for supporting a substrate W is placed in the processing chamber 101. The stage 16 may be provided with an electrode for an electrostatic chuck or a temperature regulator (e.g., heater, coolant circulation channel). The stage 16 is fixed at the bottom of the chamber body 11 via an insulating member 17. The stage 16 is connected to the ground potential via a blocking capacitor C2.

A sputter cathode 21 including the target 18 is placed in the processing chamber 101. The target 18 is formed of a carbon-based electrically conductive material such as graphite and fixed on an inner surface side of the lid 12. The sputter cathode 21 further includes a magnet unit 19. The magnet unit 19 serves to provide a magnetic field having a predetermined magnitude on the surface of the target 18 and is provided on a back side of the target 18.

In the sputter apparatus 100 having the above-mentioned configuration, plasma is generated in the processing chamber 101 by applying the RF power supply 14 having a predetermined frequency and predetermined power on the target 18 (lid 12) in a state in which an argon gas atmosphere at a predetermined pressure is maintained in the processing chamber 101. With this, Ar ions in the plasma sputter the target 18 and sputter particles (carbon particles) emitted from the target 18 are deposited on the surface of the substrate W on the stage 16. In this manner, a carbon film is formed on the surface of the substrate W.

Although a silicon substrate is typically used as the substrate W, it is not limited thereto and an insulating ceramic substrate such as a glass substrate may be used. In this embodiment, the sputter apparatus 100 forms a carbon electrode film that constitutes an electrode film of a phase-change memory element.

FIG. 2 is a schematic cross-sectional view of the phase-change memory element according to this embodiment.

A phase-change memory element 200 is formed by depositing a metal film 202, a carbon electrode film 203, a phase-change recording layer 204, a carbon electrode film 205, and a metal film 206 on an insulating layer 201 in the stated order. The metal film 202 and the carbon electrode film 203 form a lower electrode. The carbon electrode film 205 and the metal film 206 form an upper electrode. The metal films 202 and 206 are made of tungsten, for example. The carbon electrode films 203 and 205 are typically formed of sputtering films made of graphite or diamond-like carbon (DLC). The phase-change recording layer 204 is formed of a sputtering film made of a chalcogen compound, for example, Ge—Sb—Te.

The phase-change recording layer 204 has a characteristic that it exhibits a reversible phase change between a crystalline phase and an amorphous phase having resistance values different from each other due to a difference in thermal energy applied on it and those phases are stably maintained at a constant temperature. The phase-change recording layer 204 exhibits a phase change between the crystalline phase and the amorphous phase depending on degrees of heating by a current flowing between the lower electrode and the upper electrode that sandwich it and cooling due to stop of supply of that current.

As described above, the phase-change memory element 200 stores information using a difference in resistance value between the two phases different from each other, and hence provides a nonvolatile memory that does not need the supply of power for maintaining the stored data.

Here, the carbon electrode films 203 and 205, which constitute the lower electrode and the upper electrode, form interfaces of the phase-change recording layer 204. Therefore, the resistivity of the carbon electrode films 203 and 205 greatly influences the operating voltage of the phase-change memory element 200, and hence it is favorable that the resistivity of the carbon electrode films 203 and 205 is as low as possible. Further, the crystalline characteristics of the phase-change recording layer 204 strongly depend on the surface roughness of the carbon electrode film 203 that is a base material, and hence it is favorable that the surface roughness of the carbon electrode film 203 is as low as possible.

In this embodiment, the carbon electrode films 203 and 205 have a surface roughness (Rq: root-mean-square roughness) of 0.6 nm or less and a resistivity of 1.2 Ωcm or less. If the surface roughness (Rq) is above 0.6 nm, there is a fear that the phase-change recording layer 204 formed as a film on it cannot have desired crystalline characteristics. Further, if the resistivity is above 1.2 Ωcm, the operating voltage of the phase-change memory element 200 increases and there is a fear that the amount of heat generated becomes excessively large and it becomes difficult to appropriately change the phase of the phase-change recording layer 204.

The resistivity and the surface roughness of the carbon electrode films 203 and 205 largely depends on the magnitude of the DC self bias (Vdc) of a surface of a stage 16 during sputtering for film formation. As shown in FIG. 1, the DC self bias (Vdc) refers to a DC potential between the plasma and the stage 16.

Only electrons reach the stage 16 in each period during RF discharge and ions are approximately stationary. On the other hand, the stage 16 is connected to the ground via the blocking capacitor C2 and is electrically in a floating state, and hence electric charges flowing into the stage 16 are not leaked to the outside. Therefore, due to electrons accumulated on the surface of the stage 16, the stage 16 has a negative potential with respect to the plasma. This is the DC self bias (Vdc).

Although the DC self bias is generated also between the target 18 and the plasma for the same reason as described above, a focus is made only on the DC self bias (Vdc) between the stage surface and the plasma in the present specification.

As the DC self bias (Vdc) of the stage 16 surface becomes larger, the energy with which Ar ions in the plasma impinge on a substrate W becomes larger. With this, the surface shape and the resistivity of the carbon film deposited on the substrate W fluctuate.

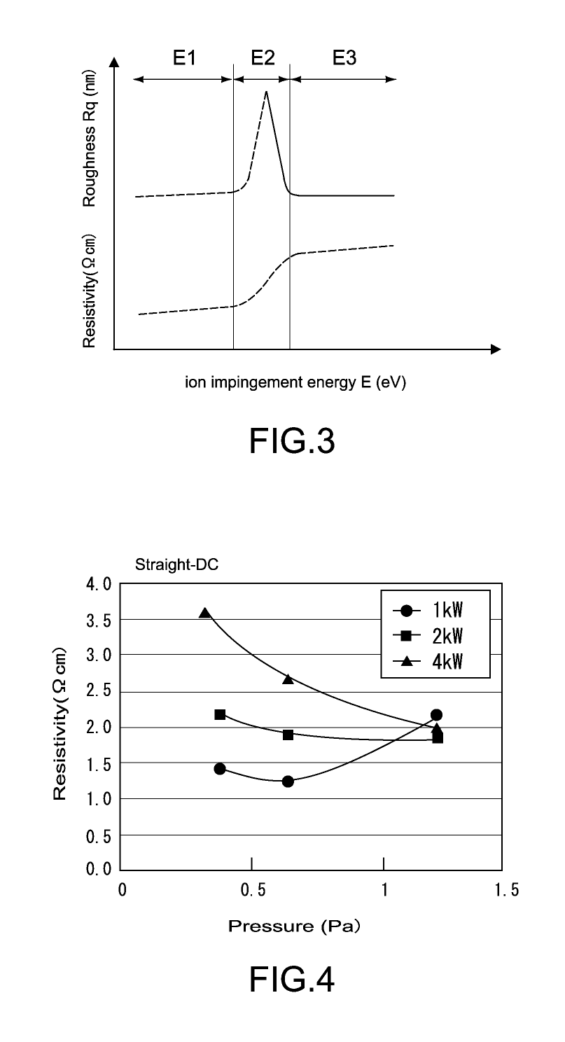

FIG. 3 is an experimental result showing a change between the surface roughness and the resistivity of the carbon film (Rq) with respect to the impingement energy of ions. Here, the thickness of the carbon film was set to 30 nm.

As shown in FIG. 3, the impingement energy of ions largely increases or fluctuates in a predetermined range (E2), and the surface roughness of the carbon film (Rq) is kept at a very low level in a range (E1) of a lower energy than E2 and in a range (E3) of a higher energy than E2. On the other hand, the resistivity of the carbon film to be formed tends to also increase, as the impingement energy of ions (DC self bias) becomes larger. The resistivity significantly increased especially in the range of the energy E2.

If the carbon film is subjected to sputtering for film formation in the Ar plasma, the energy of Ar ions entering the surface of the carbon film formed increases as Vdc becomes larger. As a result, the surface roughness of the carbon film tends to increase. However, when the incident energy of Ar ions becomes equal to or higher than the replacement energy (to 50 eV) of the carbon film, the surface of the carbon film is densified due to impingement with Ar ions and consequently the surface roughness becomes lower. Meanwhile, when Ar ions having that energy enter the carbon film, the resistivity of the carbon film increases. It may be because a ratio in which electrons in sp2 orbital of the carbon film transition to sp3 orbital increases.

The magnitude of the DC self bias (Vdc) differs also depending on the discharge methods. For the discharge method for a general sputter apparatus, a DC discharge, an AC discharge, or an RF discharge are used. A straight DC discharge or a pulse DC discharge is known as the DC discharge. Exemplifying the straight DC discharge, the pulse DC discharge, and the RF discharge, the DC self bias (Vdc) generally increases in the order of the RF discharge, the pulse DC discharge, and the straight DC discharge. In FIG. 3, the ranges of the energy E1, E2, and E3 can be considered to correspond to an RF magnetron discharge, a pulse DC magnetron discharge, and a straight DC magnetron discharge, respectively.

The DC self bias (Vdc) changes depending on a discharge pressure and power (input power) applied on the target. Hereinafter, a carbon film (thickness 30 nm) formed by straight DC magnetron sputtering will be described as an example.

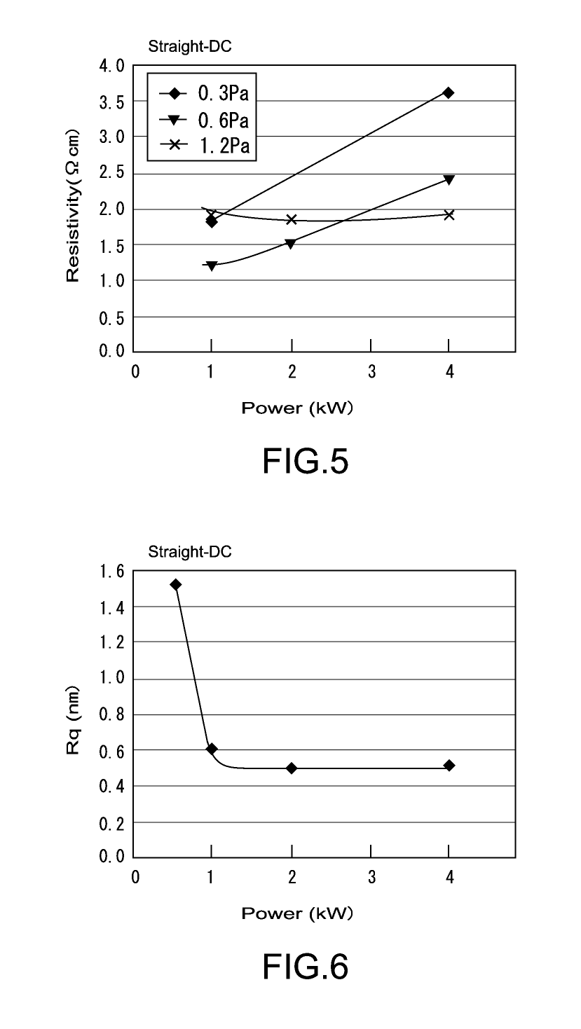

FIGS. 4 and 5 are experimental results each showing a change of the resistivity of the carbon film with respect to the discharge pressure (Ar pressure) and the power in the straight DC magnetron discharge.

Regarding the resistivity of the carbon film, it was confirmed that a lower resistivity was provided as the input power became smaller in the case of 1 Pa or less. It was confirmed that, if the input power was 2 kW or 4 kW, the resistivity decreased along with an increase of the discharge pressure, and, if the input power was 1 kW, the resistivity decreased when the pressure was equal to or lower than 0.6 Pa, and the resistivity increased when the pressure was above 0.6 Pa. A lowest resistivity was shown in the case of 1 kW and 0.6 Pa and a value thereof was about 1.2 Ωcm.

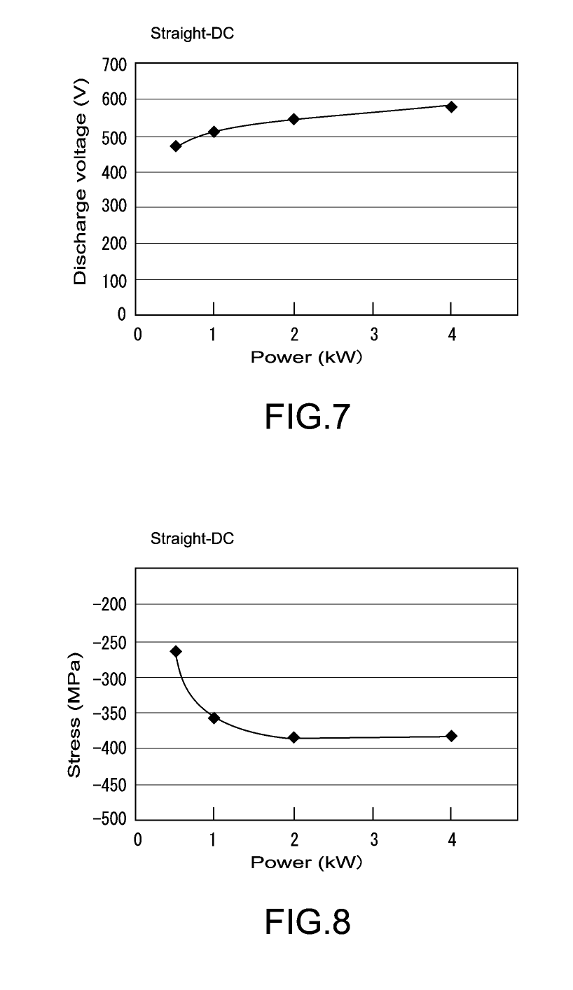

FIGS. 6 and 7 are experimental results each showing a change of the surface roughness of the carbon film (Rq) and the discharge voltage with respect to the input power in the straight DC magnetron discharge.

As shown in FIG. 6, as the input power was increased, the surface roughness (Rq) was lowered and a minimum value thereof was 0.5 nm. Further, as shown in FIG. 7, as the input power is increased, the discharge voltage also increases. Therefore, when the input power is increased and the impingement energy of Ar ions becomes larger than the replacement energy of the carbon film, the surface of the carbon film is flattened (FIG. 3).

FIG. 8 is an experimental result showing a change of a stress of the carbon film in the straight DC magnetron discharge. As the input power is increased, the compressive stress of the carbon film becomes larger. That is, it can be seen that, as the impingement energy of Ar ions becomes larger, the compressive stress of the carbon film becomes larger. With this, it is presumed that the surface roughness of the carbon film (Rq) is lowered.

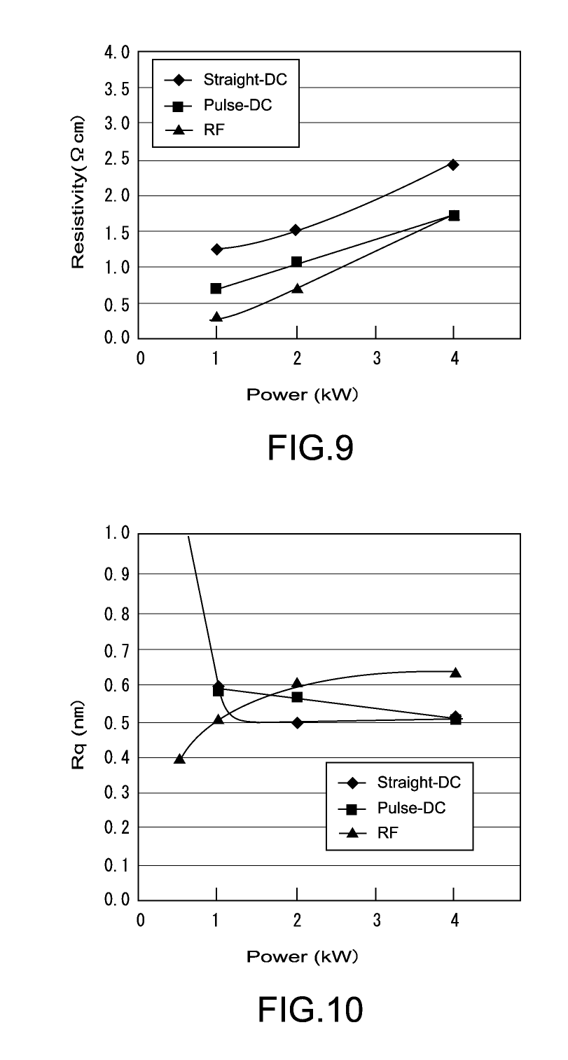

FIGS. 9 and 10 are experimental results each showing a change of the surface roughness and the resistivity of the carbon film (Rq) with respect to the input power measured in each discharge method (straight DC, pulse DC, RF). The thickness of the carbon film was set to 30 nm, the frequency of the pulse DC discharge was set to 20 kHz, the frequency of the RF discharge was set to 13.56 MHz, and the discharge pressure was set to 0.6 Pa.

As shown in FIG. 9, in all of the discharge methods, as the input power is lowered, the resistivity of the carbon film is lowered. When the input power is 2 kW or less, the resistivity can be made lower in the case of the pulse DC discharge in comparison with the straight DC discharge and in the case of the RF discharge in comparison with the pulse DC discharge. From this, it can be seen that it is possible to achieve a lower resistivity of the carbon film in comparison with the straight DC power supply by setting the input power supply to an alternate-current power supply such as a pulse power supply or an RF power supply. Further, as the power supply frequency becomes higher, a carbon film having a lower resistivity can be formed.

As shown in FIG. 9, when the input power was 1 kW, a resistivity of 0.7 Ωcm was obtained in the case of the pulse DC discharge and a resistivity of 0.3 Ωcm was obtained in the case of the RF discharge. Further, when the input power was 2 kW, a resistivity of 1.2 Ωcm was obtained in the case of the pulse DC discharge and a resistivity of 0.7 Ωcm was obtained in the case of the RF discharge.

On the other hand, regarding the surface roughness (Rq), as shown in FIG. 10, when the input power was 2 kW or less, it was able to be kept at 0.6 nm or less in the both cases of the pulse DC discharge and the RF discharge. For example, when the input power was 2 kW, a surface roughness (Rq) of 0.57 nm was obtained in the case of the pulse DC discharge and a surface roughness (Rq) of 0.6 nm was obtained in the case of the RF discharge. Further, when the input power was 1 kW, a surface roughness (Rq) of 0.59 nm was obtained in the case of the pulse DC discharge and a surface roughness (Rq) of 0.5 nm was obtained in the case of the RF discharge.

From the above-mentioned results, it can be seen that, as the input power becomes smaller, both of the surface roughness and the resistivity of the carbon film formed (Rq) are lowered. Therefore, although not particularly limited, the lower limit of the input power can be appropriately determined in such a range that the plasma can be stably generated. For example, the lower limit is 0.1 kW.

Further, as the alternate-current frequency of the input power becomes higher, it is conceivable that both of the surface roughness and the resistivity of the carbon film formed (Rq) are lowered. The upper limit of the alternate-current frequency can be appropriately set depending on the pressure condition and the input power. For example, the upper limit of the alternate-current frequency can be 20 kHz to 20 MHz inclusive.

In addition, as shown in FIG. 9, the resistivity of the carbon film formed by the pulse DC discharge was about ½ of the resistivity of the carbon film formed by the straight DC discharge and the resistivity of the carbon film formed by the RF discharge was about ⅓ of the resistivity of the carbon film formed by the straight DC discharge. From this, it can be presumed that, under the condition that the discharge pressure is 0.3 Pa to 1.2 Pa inclusive and the input power is 2 kW or less, the resistivity of the carbon film formed by the pulse DC discharge or the RF discharge can be kept at 1.2 Ωcm or less in the both cases.

Note that, also with the carbon film formed by any of the straight DC discharge, the pulse DC discharge, and the RF discharge, no crystalline carbon peaks were found as XRD measurement results.

As described above, in accordance with this embodiment, a carbon electrode film having a surface roughness (Rq) of 0.6 nm or less and a resistivity of 1.2 Ωcm or less can be formed.

Although the embodiment of the present invention has been described above, the present invention is not limited only to the above-mentioned embodiment and various changes may be added without departing from the gist of the present invention as a matter of course.

For example, in the above-mentioned embodiment, the RF magnetron discharge type sputter apparatus has been described as an example. However, it is also possible to form a carbon electrode film by the use of a pulse DC discharge type sputter apparatus. In this case, instead of the blocking capacitor C1 and the RF power supply 14, a pulse DC power supply is connected. The frequency of the pulse DC power supply can be set to 20 kHz or more, for example.

Further, in the above-mentioned embodiment, the example in which the present invention is applied to formation of the carbon electrode films 203 and 205 of the phase-change memory element 200 has been described. However, the present invention may be applied only to formation of the carbon electrode film 203 on the side of the lower electrode, for example.

In addition, the carbon electrode film described in the embodiment above may be subjected to film formation processing at a predetermined substrate temperature or may be subjected to annealing processing at a predetermined temperature after film formation. With this, control on the surface roughness and a further reduction of the resistivity can be achieved.

Note that a phase-change memory cell includes a phase-change memory element and a selection element called selector in some cases. The carbon electrode film described in the embodiment above exerts similar effects if it is employed as an electrode used in this selector. Further, the selector includes upper and lower electrodes and is formed with the phase-change memory element in series. Either one of them or the both of them may be formed of the carbon electrode film described in the embodiment above. Further, the selector may be provided above the phase-change memory element or may be provided below it.

### DESCRIPTION OF REFERENCE NUMERALS

100 sputter apparatus
200 phase-change memory element
203, 205 carbon electrode film
204 phase-change recording layer

1. A carbon electrode film forming method, comprising:
maintaining an argon gas atmosphere of 0.3 Pa to 1.2 Pa inclusive inside a chamber; and
applying a power supply having a frequency of 20 kHz to 20 MHz inclusive and a power of 0.1 kW to 2 kW inclusive on a carbon target placed in the chamber, to thereby sputter the target and deposit carbon particles on a substrate placed facing the target.

2. The carbon electrode film forming method according to claim 1, wherein
a sputter method for the target is RF magnetron sputtering.

3. The carbon electrode film forming method according to claim 1, wherein
a sputter method for the target is pulse DC magnetron sputtering.

4. The carbon electrode film forming method according to claim 1, wherein
a pressure inside the chamber is 0.6 Pa.

5. The carbon electrode film forming method according to claim 1, wherein
power of the power supply is 0.1 kW to 1 kW inclusive.

6. A carbon electrode that is formed as a film by sputtering and has a surface roughness (Rq) of 0.6 nm or less and a resistivity of 1.2 Ωcm or less.

7. A phase-change memory element manufacturing method, comprising:
maintaining an argon gas atmosphere of 0.3 Pa to 1.2 Pa inclusive inside a chamber, applying a power supply having a frequency of 20 kHz to 20 MHz inclusive and a power of 0.1 kW to 2 kW inclusive on a carbon target placed in the chamber, to thereby sputter the target, and forming a first carbon electrode film on a substrate placed facing the target; and
forming a phase-change recording layer on the first carbon electrode film.

8. The phase-change memory element manufacturing method according to claim 7, further comprising:
maintaining an argon gas atmosphere of 0.3 Pa to 1.2 Pa inclusive inside a chamber, applying a power supply having a frequency of 20 kHz to 20 MHz inclusive and a power of 0.1 kW to 2 kW inclusive on a carbon target placed in the chamber, to thereby sputter the target, and forming a second carbon electrode film on the phase-change recording layer.
